(19) United States
(12) Patent Application Publication
(10) Pub. No.: US 2026/0074146 A1
(43) Pub. Date: Mar. 12, 2026

(54) PLASMA PROCESSING APPARATUS AND PLASMA GENERATING METHOD

(71) Applicant: Tokyo Electron Limited, Tokyo (JP)

(72) Inventor: Masaki HIRAYAMA, Tokyo (JP)

(21) Appl. No.: 19/323,549

(22) Filed: Sep. 9, 2025

(30) Foreign Application Priority Data
Sep. 11, 2024 (JP) 2024-157434

(51) Int. Cl. H01J 37/32

(52) U.S. Cl. CPC H01J 37/32137; H01J 37/32174

(57) ABSTRACT

A plasma processing apparatus includes a chamber including a plasma generation space, outer and inner emission parts extending in a circumferential direction around a central axis of the chamber and the plasma generation space to emit electromagnetic waves to the plasma generation space, and a waveguide part for supplying the electromagnetic waves to the outer and inner emission parts. The waveguide part includes a resonator having a waveguide. The resonator includes a first end constituting one end of the waveguide of the resonator, a second end constituting the other end of the waveguide of the resonator, inner slots arranged along the second end of the resonator to electromagnetically couple the waveguide to the inner emission part, and outer slots arranged along the first end of the resonator to electromagnetically couple the waveguide to the outer emission part.

### CROSS-REFERENCE TO RELATED APPLICATION

This application is based upon and claims the benefit of priority from Japanese Patent Application No. 2024-157434, filed on September, 11, 2024, the entire contents of which are incorporated herein by reference.

### TECHNICAL FIELD

The present disclosure relates to a plasma processing apparatus and a plasma generating method.

### BACKGROUND

A plasma processing apparatus is used in processing a substrate. As one type of plasma processing apparatus, there is known a plasma processing apparatus that excites a gas using radio-frequency waves, such as VHF waves or UHF waves. Patent Document 1 discloses the plasma processing apparatus which includes a processing container, a stage, an upper electrode, an introduction part, and a waveguide part. The stage is provided inside the processing container. The upper electrode is provided above the stage via a space in the processing container. The introduction part is a part through which the radio-frequency waves are introduced. The introduction part is provided at a lateral end portion of the space and extends in a circumferential direction around a central axis of the processing container. The waveguide part is configured to supply the radio-frequency waves to the introduction part. The waveguide part includes a resonator that provides a waveguide. The waveguide of the resonator extends in the circumferential direction around the central axis, extends in a direction in which the central axis extends, and is connected to the introduction part.

### PRIOR ART DOCUMENT

### Patent Document

Patent Document 1: Japanese Laid-Open Patent Publication No. 2020-092031

### SUMMARY

According to an embodiment of the present disclosure, a plasma processing apparatus includes: a chamber including a plasma generation space; an outer emission part and an inner emission part which extend in a circumferential direction around a central axis of the chamber and the plasma generation space and are configured to emit electromagnetic waves to the plasma generation space, the outer emission part extending radially outside the inner emission part with respect to the central axis; and a waveguide part configured to supply the electromagnetic waves to the outer emission part and the inner emission part. The waveguide part includes a resonator provided with a waveguide. The resonator includes: a first end which constitutes one end of the waveguide of the resonator and extends in the circumferential direction around the central axis; a second end which constitutes the other end of the waveguide of the resonator and extends in the circumferential direction around the central axis; a plurality of inner slots which is arranged along the second end of the resonator, arranged in the circumferential direction around the central axis above the inner emission part, and configured to electromagnetically couple the waveguide and the inner emission part to each other; and a plurality of outer slots arranged along the first end of the resonator, arranged in the circumferential direction around the central axis above the outer emission part, and configured to electromagnetically couple the waveguide and the outer emission part to each other.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing a plasma processing apparatus according to an exemplary embodiment.

FIG. 2 is a cross-sectional view taken along line II-II in FIG. 1.

FIG. 3 is a diagram showing a plasma processing apparatus according to another exemplary embodiment.

FIG. 4 is a cross-sectional view taken along line IV-IV in FIG. 3.

FIG. 5 is a diagram showing an example of a switching circuit that may be used in the plasma processing apparatus shown in FIG. 3.

FIG. 6 is a diagram showing a plasma processing apparatus according to yet another exemplary embodiment.

FIG. 7 is a cross-sectional view taken along line VII-VII in FIG. 6.

FIG. 8 is a cross-sectional view taken along line VIII-VIII in FIG. 6.

FIG. 9 is a table showing examples of first to third states created in the plasma processing apparatus shown in FIG. 6.

FIG. 10 is a flowchart showing a plasma generating method according to an exemplary embodiment.

FIG. 11 is a flowchart showing a plasma generating method according to another exemplary embodiment.

### DETAILED DESCRIPTION

Various exemplary embodiments will now be described in detail with reference to the drawings, in which the same or corresponding parts are designated by the same reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

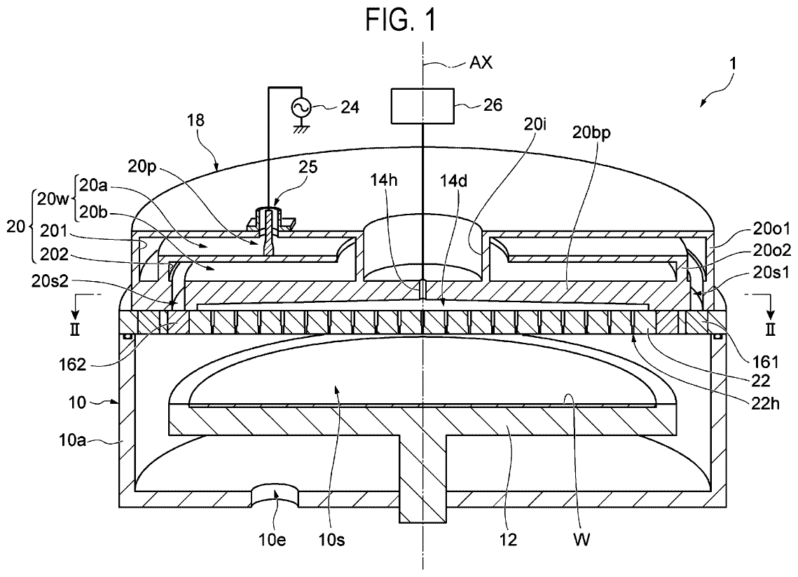

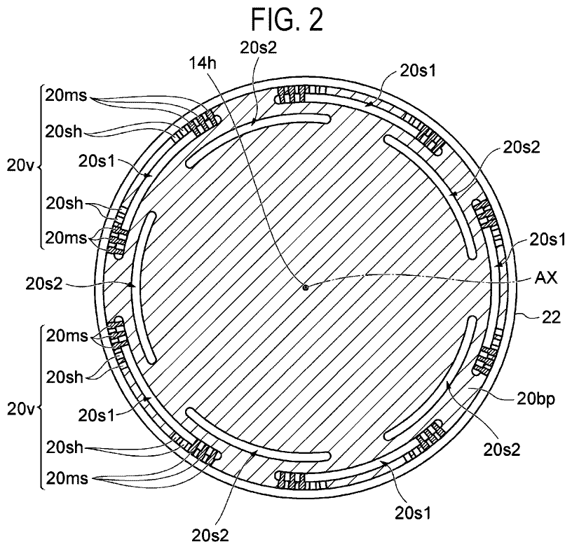

FIG. 1 is a diagram showing a plasma processing apparatus according to an exemplary embodiment. FIG. 2 is a cross-sectional view taken along line II-II in FIG. 1. A plasma processing apparatus 1 shown in FIG. 1 includes a chamber 10, an outer emission part 161, an inner emission part 162, and a waveguide part 18. The plasma processing apparatus 1 may further include a substrate support 12 and a radio-frequency power source 24.

The chamber 10 includes a processing space 10s provided therein. In the plasma processing apparatus 1, the substrate W is processed in the processing space 10s. The chamber 10 is formed of a metal such as aluminum and is grounded. The chamber 10 includes a sidewall 10a and is open at its upper end. The chamber 10 and the sidewall 10a may have a substantially cylindrical shape. The processing space 10s is provided inward of the sidewall 10a. A central axis of each of the chamber 10, the sidewall 10a, and the processing space 10s is referred to as an axis AX. The chamber 10 may include a corrosion-resistant film on its surface. The corrosion-resistant film may be an yttrium oxide film, an yttrium oxide fluoride film, an yttrium fluoride film, or a ceramic film containing yttrium oxide or an yttrium fluoride.

A bottom portion of the chamber 10 provides an exhaust port 10e. The exhaust port 10e is connected to an exhaust system. The exhaust system may include a vacuum pump, such as a dry pump and/or a turbomolecular pump, and an automatic pressure control valve.

The substrate support 12 is provided in the processing space 10s. The substrate support 12 is configured to substantially horizontally support the substrate W placed on an upper surface of the substrate support 12. The substrate support 12 has a substantially disk-like shape. A central axis of the substrate support 12 is the axis AX.

The outer emission part 161 and the inner emission part 162 are provided to emit electromagnetic waves into a plasma generation space. The outer emission part 161 and the inner emission part 162 are formed of a dielectric material such as quartz, aluminum nitride, or aluminum oxide. The outer emission part 161 and the inner emission part 162 extend along a circumferential direction around the axis AX. The outer emission part 161 extends outward of the inner emission part 162 in a radial direction with respect to the axis AX. Each of the outer emission part 161 and the inner emission part 162 may have a ring shape.

In one embodiment, the plasma generation space extends inside the processing space 10s and directly beneath an excitation electrode. In one embodiment, the excitation electrode includes a shower plate 22, and the plasma generation space is provided directly below the shower plate 22.

The shower plate 22 may be formed of a metal such as aluminum. The shower plate 22 provides a plurality of gas holes 22h. The plurality of gas holes 22h extend in a thickness direction (vertical direction) of the shower plate 22 and penetrate the shower plate 22. The outer emission part 161 and the inner emission part 162 extend so as to surround a central portion of the shower plate 22 including the plurality of gas holes 22h. The outer emission part 161, the inner emission part 162 and the shower plate 22 are arranged so as to close the opening formed at the upper end of the chamber 10.

The shower plate 22 is provided below the resonator 20 of the waveguide part 18. The shower plate 22 extends over the plasma generation space. The shower plate 22 and a bottom plate 20bp of the resonator 20 define a gas diffusion space 14d therebetween. A central axis of the gas diffusion space 14d may be the axis AX. The plurality of gas holes 22h of the shower plate 22 are connected to the gas diffusion space 14d. The resonator 20 also provides an inlet 14h. The inlet 14h may extend on the axis AX. The inlet 14h is connected to the gas diffusion space 14d. A gas supply 26 is connected to the gas diffusion space 14d. The gas output from the gas supply 26 is supplied to the plasma generation space via the inlet 14h, the gas diffusion space 14d, and the plurality of gas holes 22h.

In the plasma processing apparatus 1, plasma is generated by exciting a gas in the plasma generation space by the electromagnetic waves emitted into the plasma generation space from the outer emission part 161 and the inner emission part 162. The electromagnetic waves emitted into the plasma generation space from the outer emission part 161 and the inner emission part 162 may be radio-frequency waves such as VHF waves or UHF waves.

The waveguide part 18 is configured to supply the electromagnetic waves to the outer emission part 161 and the inner emission part 162. The waveguide part 18 includes the resonator 20. The resonator 20 may be provided above the chamber 10. The resonator 20 includes a waveguide 20w.

The resonator 20 includes a coupling portion 20p. The coupling portion 20p is an entrance through which the electromagnetic waves enter the waveguide 20w. The electromagnetic waves are generated based on radio-frequency power generated by the radio-frequency power source 24. The radio-frequency power source 24 may be configured to be able to change a frequency of the radio-frequency power to be output therefrom. The radio-frequency power source 24 is electrically connected to the coupling portion 20p. The radio-frequency power source 24 and the coupling portion 20p may be electrically connected to each other via a coaxial connector 25. The resonator 20 resonates the electromagnetic waves input to the coupling portion 20p inside the waveguide 20w and propagates the electromagnetic waves toward the outer emission part 161 and the inner emission part 162. The electromagnetic waves are emitted from the outer emission part 161 and the inner emission part 162 to the plasma generation space.

The waveguide 20w of the resonator 20 may provide a cavity surrounded by walls. The walls of the waveguide 20w may be formed of a material such as a metal. The walls of the waveguide 20w may be formed of aluminum alloy, copper, nickel, stainless steel, or the like, and may be coated with a low-resistance material such as silver, gold, or rhodium.

The resonator 20 includes a first end 201 and a second end 202. The first end 201 and the second end 202 constitute one end and the other end of the waveguide 20w of the resonator 20. The waveguide 20w extends between the first end 201 and the second end 202. The first end 201 extends in the circumferential direction around the axis AX. The second end 202 also extends in the circumferential direction around the axis AX.

In one embodiment, the walls of the resonator 20 may include an inner circumferential portion 20i, a first outer circumferential portion 20o1, and a second outer circumferential portion 20o2. The inner circumferential portion 20i extends around the axis AX, which is its central axis, and has a substantially cylindrical shape. Each of the first outer circumferential portion 20o1 and the second outer circumferential portion 20o2 extends coaxially with the inner circumferential portion 20i around the axis AX and has a substantially cylindrical shape. The second outer circumferential portion 20o2 extends inside the first outer circumferential portion 20o1 in the radial direction with respect to the axis AX. Each of the inner circumferential portion 20i, the first outer circumferential portion 20o1, and the second outer circumferential portion 20o2 may be constituted with a cylindrical plate-shaped body or may be constituted with a plurality of columnar bodies arranged along the circumferential direction.

The waveguide 20w may have a layered structure in which the waveguide 20w extends between the first outer circumferential portion 20o1 and the inner circumferential portion 20i, folds backward along the inner circumferential portion 20i, and extends between the inner circumferential portion 20i and the second outer circumferential portion 20o2. In this case, the walls of the waveguide 20w may include, in addition to the inner circumferential portion 20i, the first outer circumferential portion 20o1, and the second outer circumferential portion 20o2, a plurality of walls extending horizontally to form the layered structure.

The waveguide 20w may include an upper portion 20a constituting an uppermost layer of the layered structure and a lower portion 20b constituting a lowermost layer of the layered structure. The upper portion 20a may provide the first end 201, that is, an upper end, at the first outer circumferential portion 20o1. The lower portion 20b may provide the second end 202, that is, a lower end, at the second outer circumferential portion 20o2.

The coupling portion 20p may be provided in the upper portion 20a. In this case, an inner conductor of the coaxial connector 25 is connected to a wall of the waveguide 20w that defines the upper portion 20a from below, and an outer conductor of the coaxial connector 25 is connected to a wall (upper wall) of the waveguide 20w that defines the upper portion 20a from above.

The resonator 20 further includes a plurality of outer slots 20s1 and a plurality of inner slots 20s2. The plurality of outer slots 20s1 extend long in the circumferential direction with respect to the axis AX. The plurality of outer slots 20s1 are arranged along the first end 201 in the vicinity of the first end 201. The plurality of outer slots 20s1 are arranged along the circumferential direction around the axis AX above the outer emission part 161. The plurality of outer slots 20s1 may be arranged at equal intervals along the circumferential direction. The plurality of outer slots 20s1 electromagnetically couple the waveguide 20w and the outer emission part 161 to each other.

The inner slots 20s2 extend long in the circumferential direction with respect to the axis AX. The inner slots 20s2 are arranged along the second end 202 in the vicinity of the second end 202. The inner slots 20s2 are arranged along the circumferential direction around the axis AX above the inner emission part 162. The inner slots 20s2 may be arranged at equal intervals along the circumferential direction. The inner slots 20s2 electromagnetically couple the waveguide 20w and the inner emission part 162 to each other.

In one embodiment, the inner slots 20s2 and the outer slots 20s1 may be alternately arranged along the circumferential direction. That is, the inner slots 20s2 and the outer slots 20s1 may be arranged such that a plurality of radial lines respectively connecting the axis AX and the centers of the inner slots 20s2 and a plurality of radial lines respectively connecting the axis AX and the outer slots 20s1 are alternately arranged along the circumferential direction.

In one embodiment, the resonator 20 may further include a plurality of changing mechanisms 20v. In the example of FIGS. 1 and 2, the plurality of changing mechanisms 20v are configured to be able to change a length of each of the plurality of outer slots 20s1 (an effective length of the slot) in the circumferential direction. The effective length of the slot in the circumferential length is a circumferential length of a portion of the slot that effectively contributes to the emission of the electromagnetic waves.

Each of the changing mechanisms 20v includes a plurality of screw holes 20sh and at least one screw 20 ms. The plurality of screw holes 20sh are arranged in the circumferential direction along one of a pair of circumferentially-extending edges of a corresponding outer slot among the plurality of outer slots 20s1, and extend in a direction intersecting one of the pair of circumferentially-extending edges (e.g., in the radial direction). One half of the plurality of screw holes 20sh may be arranged in the circumferential direction from one circumferential end of the corresponding outer slot, and the other half of the plurality of screw holes 20sh may be arranged in the circumferential direction from the other circumferential end of the corresponding outer slot.

The at least one screw 20 ms is threadedly coupled into at least one screw hole selected from the plurality of screw holes 20sh, and crosses the corresponding outer slot in the radial direction to bring into contact with the other of the pair of circumferentially-extending edges of the corresponding outer slot. In each of the plurality of changing mechanisms 20v, an even number of screws 20 ms may be threadedly coupled into the selected even number of screw holes 20sh so as to change a circumferential length of the corresponding outer slot without changing a center position of the corresponding outer slot in the circumferential direction. With such a plurality of changing mechanisms 20v, the circumferential length of the plurality of outer slots 20s1 may be adjusted, and an intensity (electric field intensity) of the electromagnetic waves emitted from the plurality of outer slots 20s1 may be adjusted.

In the plasma processing apparatus 1, resonance of the electromagnetic waves occurs between the first end 201 and the second end 202 of the resonator 20. The electromagnetic waves resonated in the resonator 20 are emitted from the plurality of outer slots 20s1 via the outer emission part 161 into the plasma generation space, and are also emitted from the plurality of inner slots 20s2 via the inner emission part 162 into the plasma generation space. The electromagnetic waves emitted into the plasma generation space propagate along the lower surface of the shower plate 22 toward the center of the shower plate 22.

In the plasma processing apparatus 1, a phase of the electromagnetic waves emitted into the plasma generation space via the outer emission part 161 and a phase of the electromagnetic waves emitted into the plasma generation space via the inner emission part 162 are different from each other by, for example, 180 degrees. Therefore, the electromagnetic waves emitted into the plasma generation space via the outer emission part 161 and the electromagnetic waves emitted into the plasma generation space via the inner emission part 162 weaken each other. However, the outer emission part 161 and the inner emission part 162 are formed at different positions in the radial direction. Therefore, in the vicinity of the outer emission part 161 and the inner emission part 162, the electromagnetic waves may exist as surface waves directly under the shower plate 22. Therefore, in a case in which the outer emission part 161 does not exist, the intensity of the electromagnetic waves directly under the center of the shower plate 22 tends to be higher than the intensity of the electromagnetic waves at other positions. However, according to the plasma processing apparatus 1, it is possible to weaken the intensity of the electromagnetic waves directly under the center of the shower plate 22. Therefore, according to the plasma processing apparatus 1, it is possible to improve a radial plasma density distribution in the plasma generation space.

Further, in the plasma processing apparatus 1, the intensity of the electromagnetic waves emitted from the outer emission part 161 into the plasma generation space may be adjusted relative to the intensity of the electromagnetic waves emitted from the inner emission part 162 into the plasma generation space using the plurality of changing mechanisms 20v. Accordingly, the plasma processing apparatus 1 may adjust the radial plasma density distribution of the electromagnetic waves in the plasma generation space. Therefore, the plasma processing apparatus 1 may adjust the radial plasma density distribution in the plasma generation space.

The plurality of changing mechanisms 20v may be provided to change the lengths of the plurality of inner slots 20s2 in addition to or instead of the plurality of outer slots 20s1.

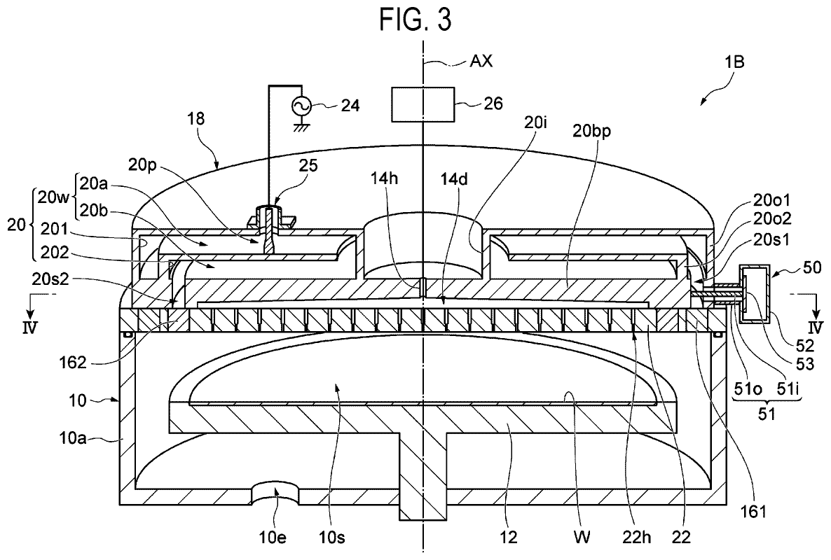

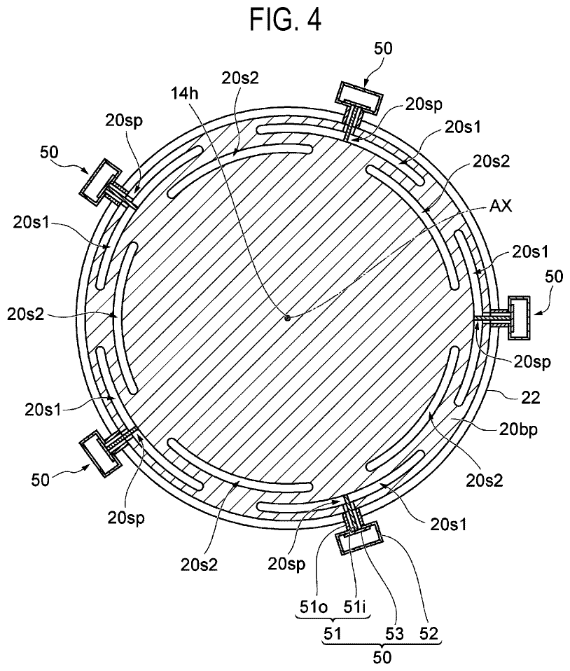

A plasma processing apparatus according to another exemplary embodiment will now be described with reference to FIGS. 3 and 4. FIG. 3 is a diagram showing the plasma processing apparatus according to another exemplary embodiment. FIG. 4 is a cross-sectional view taken along line IV-IV in FIG. 3. A plasma processing apparatus 1B shown in FIGS. 3 and 4 will be described below in terms of differences from the plasma processing apparatus 1.

The plasma processing apparatus 1B does not include the plurality of changing mechanisms 20v. In the plasma processing apparatus 1B, the resonator 20 further includes a plurality of short-circuiting mechanisms 50. The plurality of short-circuiting mechanisms 50 are configured to releasably short-circuit a plurality of regions 20sp, which are central portions in the circumferential direction of the plurality of outer slots 20s1, to the ground.

Each of the short-circuiting mechanisms 50 includes a metal-made rod 51i and a switching circuit 53. The rod 51i of each of the short-circuiting mechanisms 50 extends radially across a corresponding one of the plurality of regions 20sp. That is, the rod 51i of each of the short-circuiting mechanisms 50 extends radially across a central portion in the circumferential direction of a corresponding one of the outer slots 20s1. One end of the rod 51i of each of the short-circuiting mechanisms 50 may be connected to an outer circumferential surface of the bottom plate 20bp that defines an inner edge of the corresponding outer slot. The rod 51i may be an inner conductor of the coaxial tube 51. In this case, the outer conductor 51o of the coaxial tube 51 is connected to the first outer circumferential portion 20o1.

Each rod 51i of the plurality of short-circuiting mechanisms 50 is connected to the switching circuit 53 of a control circuit board. The control circuit board is disposed inside a shield case 52. The switching circuit 53 is configured to releasably short-circuit the rod 51i to the ground. The switching circuit 53 may have any circuit configuration as long as it may switch between short-circuiting the rod 51i to the ground and releasing the short-circuiting.

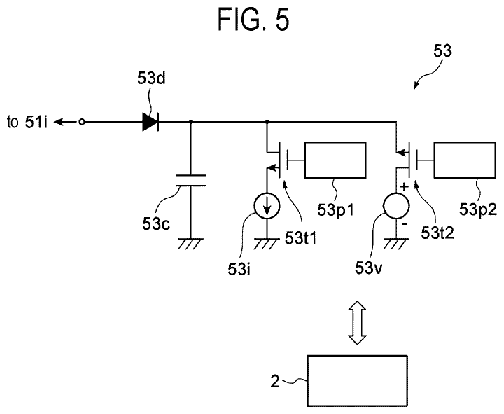

FIG. 5 is a diagram showing an example of a switching circuit that may be used in the plasma processing apparatus shown in FIG. 3. In one embodiment, the switching circuit 53 may have a configuration shown in FIG. 5. In the example of FIG. 5, the switching circuit 53 includes a diode 53d, a first switching transistor 53t1, a second switching transistor 53t2, a current source 53i, a voltage source 53v, a signal generating circuit 53p1, and a signal generating circuit 53p2.

An anode of the diode 53d is connected to the rod 51i. A cathode of the diode 53d may be connected to the ground via a capacitor 53c. The diode 53d may be a PIN diode, a Schottky diode, or the like. The diode 53d may be a diode having a small capacitance as an off-time capacitance. The capacitor 53c may have a capacitance which is determined to provide a sufficiently small impedance at a plasma excitation frequency and may have a small loss. The capacitor 53c may be a ceramic capacitor, or the like.

Each of the first switching transistor 53t1 and the second switching transistor 53t2 may be a switching transistor such as a MOSFET. Each of the first switching transistor 53t1 and the second switching transistor 53t2 is connected in parallel between the cathode of the diode 53d and the ground.

The current source 53i is, for example, a constant current source, and is connected between the first switching transistor 53t1 and the ground. The voltage source 53v is, for example, a constant voltage source, and is connected between the second switching transistor 53t2 and the ground.

A current value Is of the current source 53i is set to a value larger than an amplitude (a peak amplitude relative to 0) of a radio-frequency current Im flowing through the rod 51i. The radio-frequency current Im is a current flowing through the rod 51i when the rod 51i arranged at the corresponding region among the plurality of regions 20sp is short-circuited to the ground under plasma excitation conditions in the plasma processing apparatus 1. In addition, a voltage value Vs of the voltage source 53v is set to a value larger than an amplitude (a peak amplitude relative to 0) of a radio-frequency voltage Vm applied to the rod 51i under the plasma excitation conditions in the plasma processing apparatus 1.

The signal generating circuit 53p1 is connected to a control terminal of the first switching transistor 53t1. The signal generating circuit 53p1 switches the first switching transistor 53t1 between an ON state (closed state) and an OFF state (open state) by supplying a control signal to the control terminal of the first switching transistor 53t1. The signal generating circuit 53p2 is connected to a control terminal of the second switching transistor 53t2. The signal generating circuit 53p2 switches the second switching transistor 53t2 between an ON state (closed state) and an OFF state (open state) by supplying a control signal to the control terminal of the second switching transistor 53t2. The signal generating circuit 53p1 and the signal generating circuit 53p2 alternately set the first switching transistor 53t1 and the second switching transistor 53t2 to the ON state (closed state). The signal generating circuit 53p1 and the signal generating circuit 53p2 may be controlled by a control circuit 2 constituted with a dedicated circuit such as a computer device or an ASIC.

When the first switching transistor 53t1 of the switching circuit 53 is in the ON state (closed state), a forward current flows through the diode 53d. As a result, the corresponding outer slot is short-circuited to the ground at its center, and the emission of the electromagnetic waves from the corresponding outer slot is substantially blocked. On the other hand, when the second switching transistor 53t2 is in the ON state (closed state), a backward voltage is applied to the diode 53d, the short-circuiting at the center of the corresponding outer slot is released, and the electromagnetic waves are emitted from the corresponding outer slot toward the outer emission part 161.

According to the plasma processing apparatus 1B, it is possible to adjust a time average intensity of the electromagnetic waves emitted from the outer slots 20s1 by alternately switching between emitting the electromagnetic waves from the outer slots 20s1 and blocking the electromagnetic waves. Therefore, according to the plasma processing apparatus 1B, it is possible to adjust a radial intensity distribution of the electromagnetic waves in the plasma generation space, and it is possible to adjust the radial plasma density distribution in the plasma generation space.

The short-circuiting mechanisms 50 may be configured to switch between the short-circuiting of the plurality of regions 20sp and the release of the short-circuiting at a cycle of 1 μs or more and 100 μs or less. In this case, the short-circuiting of the plurality of regions 20sp to the ground and the release of the short-circuiting are switched at a cycle at which plasma does not respond. Therefore, it is possible to adjust the radial plasma density distribution in the plasma generation space without varying the distribution with time.

The plurality of short-circuiting mechanisms 50 may be configured to releasably short-circuit the plurality of regions, which are the central portions of the plurality of inner slots 20s2 in the circumferential direction, to the ground in addition to or instead of the plurality of outer slots 20s1.

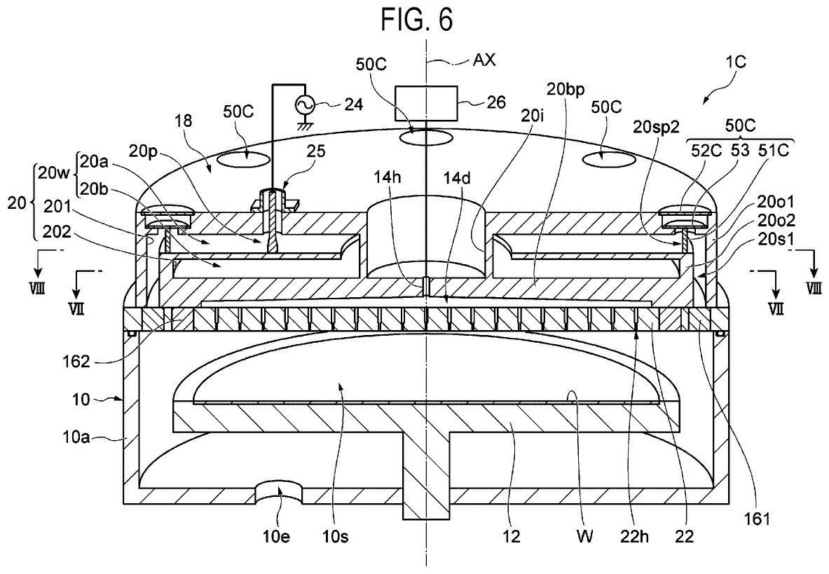

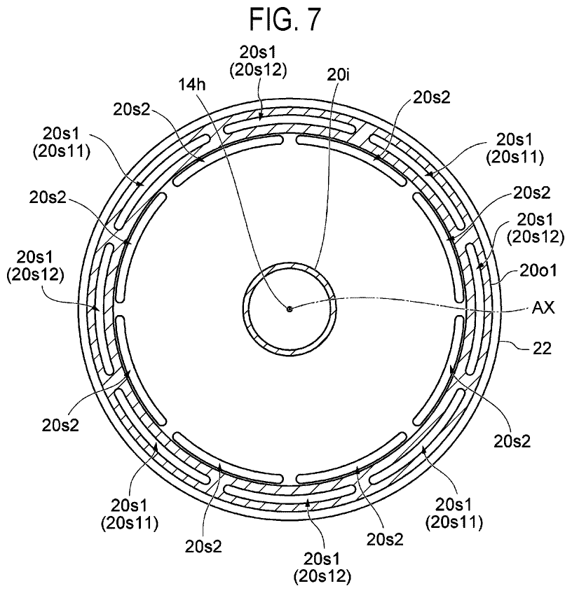

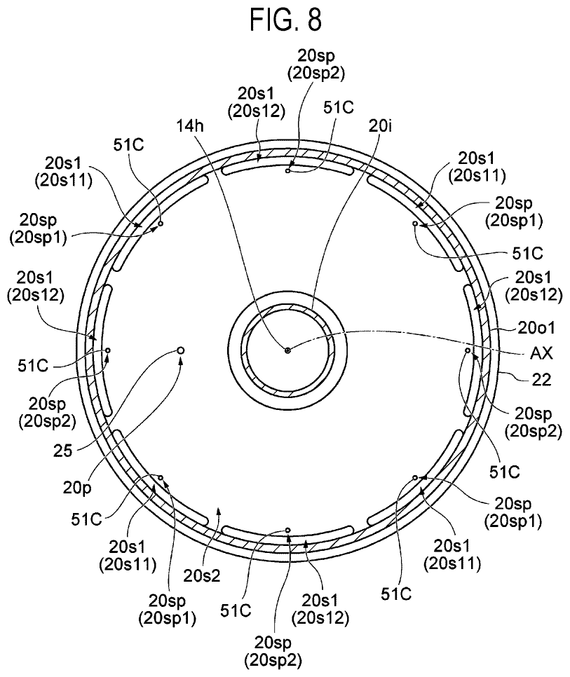

A plasma processing apparatus according to yet another exemplary embodiment will now be described with reference to FIGS. 6 to 8. FIG. 6 is a diagram showing the plasma processing apparatus according to yet another exemplary embodiment. FIG. 7 is a cross-sectional view taken along line VII-VII in FIG. 6. FIG. 8 is a cross-sectional view taken along line VIII-VIII in FIG. 6. A plasma processing apparatus 1C shown in FIGS. 6 to 8 will be described below in terms of differences from the plasma processing apparatus 1B.

The plasma processing apparatus 1C includes a plurality of short-circuiting mechanisms 50C instead of the plurality of short-circuiting mechanisms 50. The plurality of short-circuiting mechanisms 50C are configured to releasably short-circuit the plurality of regions 20sp of the waveguide 20w extending along respective circumferential centers of the plurality of outer slots 20s1 to the ground. The plurality of regions 20sp are arranged in the circumferential direction inside the upper portion 20a. The plurality of regions 20sp are located radially inward near the respective circumferential centers of the plurality of outer slots 20s1.

Each of the plurality of short-circuiting mechanisms 50C includes a switching circuit 53, just like each of the plurality of short-circuiting mechanisms 50. In each of the plurality of short-circuiting mechanisms 50C, the control circuit board that provides the switching circuit 53 is disposed in a space formed in the upper wall of the resonator 20 that defines the upper portion 20a from above, and is shielded by a lid 52C that closes the space.

A metal-made rod 51C is connected to the switching circuit 53. In the case of the switching circuit 53 of the example of FIG. 5, the rod 51C is connected to an anode of the diode 53d. One end of the rod 51C may be connected to a wall of the resonator 20 that defines the upper portion 20a from below.

In the plasma processing apparatus 1C as well, the plurality of short-circuiting mechanisms 50C may be used to switch between short-circuiting the central portions of the plurality of outer slots 20s1 and releasing the short-shorting. In the plasma processing apparatus 1C as well, a time average intensity of the electromagnetic waves emitted from the plurality of outer slots 20s1 may be adjusted by alternately switching between emitting the electromagnetic waves from the plurality of outer slots 20s1 and blocking the electromagnetic waves. Therefore, according to the plasma processing apparatus 1C, it is possible to adjust a radial intensity distribution of the electromagnetic waves in the plasma generation space, and it is possible to adjust the radial plasma density distribution in the plasma generation space.

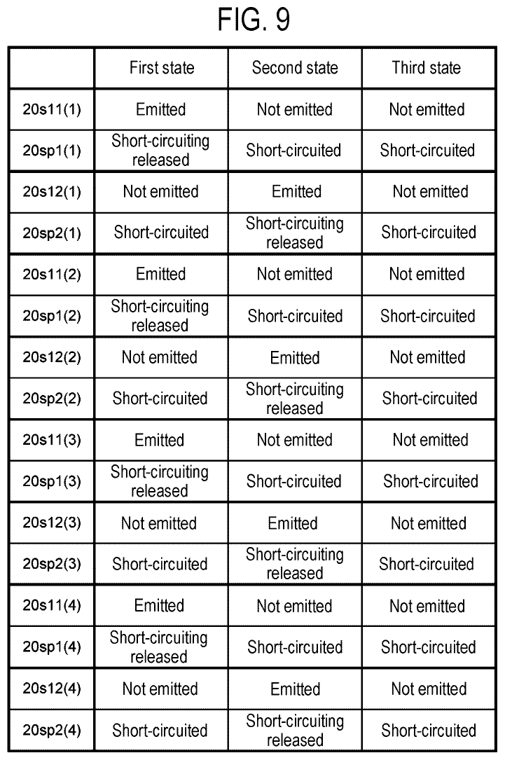

FIG. 9 is a table showing examples of first to third states created in the plasma processing apparatus shown in FIG. 6. In the plasma processing apparatus 1C, the plurality of short-circuiting mechanisms 50C may repeat a process of sequentially creating the first to third states shown in FIG. 9. In this case, the plurality of outer slots 20s1 include a plurality of first outer slots 20s11 and a plurality of second outer slots 20s12 arranged alternately along the circumferential direction. The plurality of regions 20sp include a plurality of first regions 20sp1 and a plurality of second regions 20sp2. The plurality of first regions 20sp1 are arranged along central portions of the plurality of first outer slots 20s11 in the circumferential direction. The plurality of second regions 20sp2 are arranged along central portions of the plurality of second outer slots 20s12 in the circumferential direction.

In FIG. 9, the numbers in parentheses following reference symbols of the first outer slots 20s11, the first regions 20sp1, the second outer slots 20s12, and the second regions 20sp2 indicate their orders in the circumferential direction. In the example shown in FIG. 9, the short-circuiting mechanisms 50C create the first state in which the first regions 20sp1 are released from the short-circuiting to the ground and the second regions 20sp2 are short-circuited to the ground. In the first state, the electromagnetic waves are emitted from the first outer slots 20s11 and the emission of the electromagnetic waves from the second outer slots 20s12 is blocked.

After the first state, the short-circuiting mechanisms 50C create the second state in which the first regions 20sp1 are short-circuited to the ground and the second regions 20sp2 are released from the short-circuiting to the ground. In the second state, the emission of electromagnetic waves from the first outer slots 20s11 is blocked, and the electromagnetic waves are emitted from the second outer slots 20s12.

After the second state, the short-circuiting mechanisms 50C create the third state in which the first regions 20sp1 and the second regions 20sp2 are short-circuited to the ground. In the third state, the emission of the electromagnetic waves from the first outer slots 20s11 and the second outer slots 20s12 is blocked.

Even in the example shown in FIG. 9, it is possible to adjust the radial intensity distribution of the electromagnetic waves in the plasma generation space, and it is possible to adjust the radial plasma density distribution in the plasma generation space. Further, according to the first and second states, the loss of the electromagnetic waves in each portion is reduced, and high power efficiency is obtained.

In the plasma processing apparatus 1C, the first to third states may be switched at a cycle of 1 μs or more and 100 μs or less. That is, the time length of the cycle in which the first to third states are repeatedly created may be 1 μs or more and 100 μs or less. The time lengths of the first and second states may be identical to each other, and the time length of the third state may be set so that the plasma is generated most uniformly. In this case, the short-circuiting of the plurality of regions 20sp to the ground and the release of the short-circuiting are switched at a cycle in which the plasma does not respond. Therefore, the radial plasma density distribution in the plasma generation space may be adjusted without varying the distribution with time.

The plurality of short-circuiting mechanisms 50C may be configured to releasably short-circuit the regions 20sp arranged along the circumferential centers of the inner slots 20s2 in addition to or instead of the outer slots 20s1 to the ground. The creation of the first to third states in the example shown in FIG. 9 may also be repeated in the plasma processing apparatus 1B.

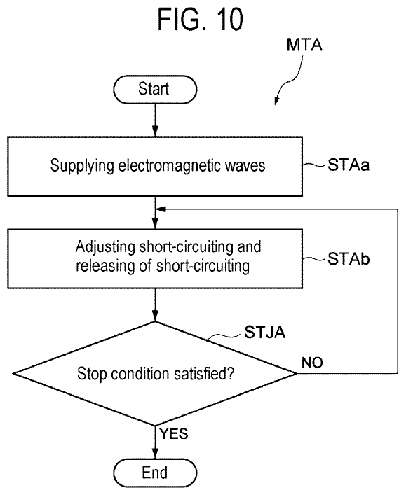

A plasma generating method according to one exemplary embodiment will now be described with reference to FIG. 10. The plasma generating method shown in FIG. 10 (hereinafter, referred to as a “method MTA”) is applied to the plasma processing apparatus 1B or 1C.

The method MTA includes Operation STAa and Operation STAb. In Operation STAa, the electromagnetic waves are supplied to the outer slots 20s1 and the inner slots 20s2 via the waveguide 20w so that they are supplied to the plasma generation space.

Operation STAb is performed in parallel with Operation STAa. In Operation STAb, an amount of the electromagnetic waves emitted from the inner slots 20s2 and/or the outer slots 20s1 is adjusted. For this purpose, the short-circuiting of the regions 20sp to the ground and the release of the short-circuiting are adjusted by the short-circuiting mechanisms (50 or 50C). The operation of the short-circuiting mechanisms (50 or 50C) is referenced in the above descriptions on the plasma processing apparatus 1B and the plasma processing apparatus 1C.

The method MTA may further include Operation STJA. In Operation STJA, it is determined whether or not a stop condition is satisfied. The stop condition is satisfied when an end condition of the process is satisfied. When it is determined in Operation STJA that the stop condition is not satisfied, Operation STAb is repeated in parallel with Operation STAa. In the repetition of Operation STAb, the short-circuiting of the plurality of regions 20sp to the ground and the release of the short-circuiting may be switched at a cycle of 1 μs or more and 100 μs or less. On the other hand, when it is determined in Operation STJA that the stop condition is satisfied, the method MTA ends.

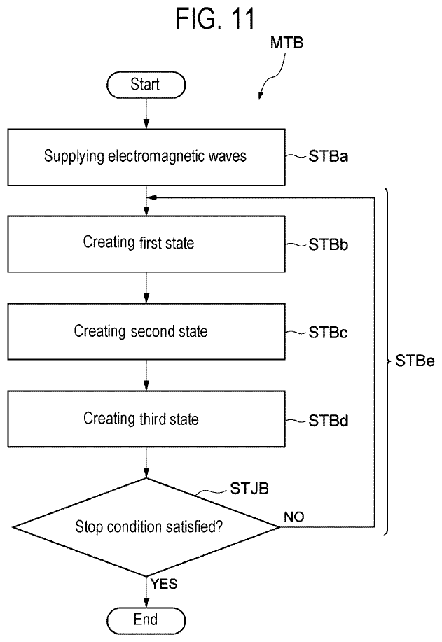

A plasma generating method according to another exemplary embodiment will now be described with reference to FIG. 11. The plasma generating method shown in FIG. 11 (hereinafter, referred to as “method MTB”) is applied to the plasma processing apparatus 1B or 1C.

The method MTB includes Operations STBa to STBe. In Operation STBa, the electromagnetic waves are supplied to the outer slots 20s1 and the inner slots 20s2 via the waveguide 20w so that they are supplied to the plasma generation space.

Operations STBb to STBe are performed in parallel with Operation STBa. In Operations STBb to STBd, the above-described first to third states are sequentially created. In Operation STBe, Operations STBb to STBd are repeated. Operations STBb to STBd may be repeated at a cycle of 1 μs or more and 100 μs or less.

Operation STBe may further include Operation STJB. In Operation STJB, it is determined whether or not a stop condition is satisfied. The stop condition is satisfied when an end condition of the process is satisfied. When it is determined in Operation STJB that the stop condition is not satisfied, Operations STBb to STBd are repeated in parallel with Operation STBa. On the other hand, when it is determined in Operation STJB that the stop condition is satisfied, the method MTB ends.

Although various exemplary embodiments have been described above, the present disclosure is not limited to the above-described exemplary embodiments, and various additions, omissions, substitutions, and modifications may be made. In addition, elements in different embodiments may be combined to each other to provide other embodiments.

For example, in the above-described embodiments, the outer emission part 161 and the inner emission part 162 are separate bodies, but in other embodiments, the outer emission part 161 and the inner emission part 162 may be configured as an integral or single object formed of a dielectric material. That is, the scope of the present disclosure also includes an embodiment in which a portion of the integral or single object formed of the dielectric material, which corresponds to the plurality of outer slots 20s1, is used as the outer emission part 161, and another portion of the object, which corresponds to the plurality of inner slots 20s2, is used as the inner emission part 162.

Various exemplary embodiments included in the present disclosure will be listed in [E1] to [E15] below.

### E1

A plasma processing apparatus includes:
a chamber including a plasma generation space;
an outer emission part and an inner emission part which extend in a circumferential direction around a central axis of the chamber and the plasma generation space and are configured to emit electromagnetic waves to the plasma generation space, the outer emission part extending radially outside the inner emission part with respect to the central axis; and
a waveguide part configured to supply the electromagnetic waves to the outer emission part and the inner emission part,
wherein the waveguide part includes a resonator provided with a waveguide, and
wherein the resonator includes:
a first end which constitutes one end of the waveguide of the resonator and extends in the circumferential direction around the central axis;
a second end which constitutes the other end of the waveguide of the resonator and extends in the circumferential direction around the central axis;
a plurality of inner slots which is arranged along the second end of the resonator, arranged in the circumferential direction around the central axis above the inner emission part, and configured to electromagnetically couple the waveguide and the inner emission part to each other; and
a plurality of outer slots arranged along the first end of the resonator, arranged in the circumferential direction around the central axis above the outer emission part, and configured to electromagnetically couple the waveguide and the outer emission part to each other.

### E2

In the plasma processing apparatus of [E1] above, the plurality of inner slots and the plurality of outer slots are alternately arranged along the circumferential direction.

### E3

In the plasma processing apparatus of [E1] or [E2] above, the resonator further includes a plurality of changing mechanisms configured to change a length of at least one of the plurality of inner slots or each of the plurality of outer slots along the circumferential direction.

### E4

In the plasma processing apparatus of [E3] above, each of the plurality of changing mechanisms includes:
a plurality of screw holes arranged in the circumferential direction along a first edge of a pair of edges extending in the circumferential direction along at least one of a corresponding inner slot of the plurality of inner slots or a corresponding outer slot of the plurality of outer slots, and configured to extend in a direction intersecting the first edge of the pair of edges; and
a screw threadedly coupled into a screw hole selected from the plurality of screw holes and configured to be brought into contact with a second edge of the pair of edges.

### E5

In the plasma processing apparatus of [E1] or [E2] above, the resonator further includes a plurality of short-circuiting mechanisms configured to releasably short-circuit, to a ground, a plurality of portions, which are central portions of at least one of the plurality of inner slots or the plurality of outer slots in the circumferential direction, or a plurality of portions of the waveguide along the central portions.

### E6

In the plasma processing apparatus of [E5] above, each of the plurality of short-circuiting mechanisms includes:
a metal-made rod extending across a corresponding portion of the plurality of portions; and
a switching circuit configured to releasably short-circuit the metal-made rod to the ground.

### E7

In the plasma processing apparatus of [E6] above, the switching circuit includes:
a diode including a cathode and an anode connected to the metal-made rod;
a first switching transistor connected to the cathode;
a current source connected between the first switching transistor and the ground;
a second switching transistor connected to the cathode in parallel with the first switching transistor;
a voltage source connected between the second switching transistor and the ground; and
a signal generation circuit configured to alternately set the first switching transistor and the second switching transistor to a closed state,
wherein a current value of the current source is set to a value greater than an amplitude of a radio-frequency current of the electromagnetic waves flowing through the metal-made rod when the metal-made rod is short-circuited to the ground in the corresponding portion, and
wherein a voltage value of the voltage source is set to a value greater than an amplitude of a radio-frequency voltage of the electromagnetic waves in the corresponding portion.

### E8

In the plasma processing apparatus of [E6] or [E7] above, the plurality of short-circuiting mechanisms are configured to switch between the short-circuiting of the plurality of portions to the ground and the release of the short-circuiting at a cycle of 1 μs or more and 100 μs or less.

### E9

In the plasma processing apparatus of any one of [E5] to [E7] above, the plurality of outer slots include a plurality of first outer slots and a plurality of second outer slots which are arranged alternately along the circumferential direction,
the plurality of portions include:
a plurality of first portions which are either the central portions of the plurality of first outer slots in the circumferential direction or portions arranged along the central portions of the plurality of first outer slots in the circumferential direction; and
a plurality of second portions which are either the central portions of the plurality of second outer slots in the circumferential direction or portions arranged along the central portions of the plurality of second outer slots in the circumferential direction, and
the plurality of short-circuiting mechanisms are configured to repeat:
creating a first state in which the plurality of first portions are released from the short-circuiting to the ground and the plurality of second portions are short-circuited to the ground;
after the first state, creating a second state in which the plurality of first portions are short-circuited to the ground and the plurality of second portions are released from the short-circuiting to the ground; and
after the second state, creating a third state in which the plurality of first portions and the plurality of second portions are short-circuited to the ground.

### E10

In the plasma processing apparatus of [E9] above, the plurality of short-circuiting mechanisms are configured to sequentially switch between the first state, the second state, and the third state at a cycle of 1 μs or more and 100 μs or less.

### E11

In the plasma processing apparatus of any one of [E1] to [E10] above, the resonator includes:
an inner circumferential portion extending around the central axis;
a first outer circumferential portion extending around the central axis;
a second outer circumferential portion extending around the central axis inside the first outer circumferential portion;
the waveguide having a layered structure in which the waveguide extends between the first outer circumferential portion and the inner circumferential portion, folds backward along the inner circumferential portion, and extends between the inner circumferential portion and the second outer circumferential portion;
an upper portion located in an uppermost layer of the layered structure and configured to provide the first end at the first outer circumferential portion; and
a lower portion located in a lowermost layer of the layered structure and configured to provide the second end at the second outer circumferential portion.

### E12

A plasma generating method in the plasma processing apparatus of any one of [E6] to [E10] above includes:
(a) supplying the electromagnetic waves to the plurality of outer slots and the plurality of inner slots via the waveguide so that the electromagnetic waves are supplied to the plasma generation space; and
(b) adjusting the short-circuiting of the plurality of portions to the ground and the release of the short-circuiting by the plurality of short-circuiting mechanisms to adjust an amount of electromagnetic waves emitted from at least one of the plurality of inner slots or the plurality of outer slots.

### E13

In the plasma generating method of [E12] above, in (b), the short-circuiting of the plurality of portions to the ground and the release of the short-circuiting are switched at a cycle of 1 μs or more and 100 μs or less.

### E14

A plasma generating method in the plasma processing apparatus of [E9] or [E10] above includes:
(a) supplying the electromagnetic waves to the plurality of outer slots and the plurality of inner slots via the waveguide so that the electromagnetic waves are supplied to the plasma generation space;
(b) creating a first state in which the plurality of first portions are released from the short-circuiting to the ground and the plurality of second portions are short-circuited to the ground by the plurality of short-circuiting mechanisms;
(c) after (b), creating a second state in which the plurality of first portions are short-circuited to the ground and the plurality of second portions are released from the short-circuiting to the ground by the plurality of short-circuiting mechanisms;
(d) after (c), creating a third state in which the plurality of first portions and the plurality of second portions are short-circuited to the ground; and
(e) sequentially repeating (b), (c), and (d).

### E15

In the plasma generating method of [E14] above, the first state, the second state, and the third state are sequentially switched at a cycle of 1 μs or more and 100 μs or less.

According to the present disclosure in some embodiments, it is possible to improve a radial plasma density distribution in a plasma generation space.

From the foregoing description, it should be understood that various embodiments of the present disclosure have been described herein for purposes of illustration, and that various modifications can be made without departing from the scope and spirit of the present disclosure. Accordingly, the various embodiments disclosed herein are not intended to be limiting, and the true scope and spirit of the present disclosure are indicated by the appended claims.

What is claimed is:

1. A plasma processing apparatus, comprising:
a chamber including a plasma generation space;
an outer emission part and an inner emission part which extend in a circumferential direction around a central axis of the chamber and the plasma generation space and are configured to emit electromagnetic waves to the plasma generation space, the outer emission part extending radially outside the inner emission part with respect to the central axis; and
a waveguide part configured to supply the electromagnetic waves to the outer emission part and the inner emission part,
wherein the waveguide part includes a resonator provided with a waveguide, and
wherein the resonator includes:
a first end which constitutes one end of the waveguide of the resonator and extends in the circumferential direction around the central axis;
a second end which constitutes the other end of the waveguide of the resonator and extends in the circumferential direction around the central axis;
a plurality of inner slots arranged along the second end of the resonator, arranged in the circumferential direction around the central axis above the inner emission part, and configured to electromagnetically couple the waveguide and the inner emission part to each other; and
a plurality of outer slots arranged along the first end of the resonator, arranged in the circumferential direction around the central axis above the outer emission part, and configured to electromagnetically couple the waveguide and the outer emission part to each other.

2. The plasma processing apparatus of claim 1, wherein the plurality of inner slots and the plurality of outer slots are alternately arranged along the circumferential direction.

3. The plasma processing apparatus of claim 2, wherein the resonator further includes a plurality of changing mechanisms configured to change a length of at least one of each of the plurality of inner slots or each of the plurality of outer slots along the circumferential direction.

4. The plasma processing apparatus of claim 3, wherein each of the plurality of changing mechanisms includes:
a plurality of screw holes arranged in the circumferential direction along a first edge of a pair of edges extending in the circumferential direction along at least one of a corresponding inner slot of the plurality of inner slots or a corresponding outer slot of the plurality of outer slots, and configured to extend in a direction intersecting the first edge of the pair of edges; and
a screw threadedly coupled into a screw hole selected from the plurality of screw holes and configured to be brought into contact with a second edge of the pair of edges.

5. The plasma processing apparatus of claim 1, wherein the resonator further includes a plurality of short-circuiting mechanisms configured to releasably short-circuit, to a ground, a plurality of portions, which are central portions of at least one of the plurality of inner slots or the plurality of outer slots in the circumferential direction, or a plurality of portions of the waveguide along the central portions.

6. The plasma processing apparatus of claim 5, wherein each of the plurality of short-circuiting mechanisms includes:
a metal-made rod extending across a corresponding portion of the plurality of portions; and
a switching circuit configured to releasably short-circuit the metal-made rod to the ground.

7. The plasma processing apparatus of claim 6, wherein the switching circuit includes:
a diode including a cathode and an anode connected to the metal-made rod;
a first switching transistor connected to the cathode;
a current source connected between the first switching transistor and the ground;
a second switching transistor connected to the cathode in parallel with the first switching transistor;
a voltage source connected between the second switching transistor and the ground; and
a signal generation circuit configured to alternately set the first switching transistor and the second switching transistor to a closed state,
wherein a current value of the current source is set to a value greater than an amplitude of a radio-frequency current of the electromagnetic waves flowing through the metal-made rod when the metal-made rod is short-circuited to the ground in the corresponding portion, and
wherein a voltage value of the voltage source is set to a value greater than an amplitude of a radio-frequency voltage of the electromagnetic waves in the corresponding portion.

8. The plasma processing apparatus of claim 6, wherein the plurality of short-circuiting mechanisms are configured to switch between the short-circuiting of the plurality of portions to the ground and the release of the short-circuiting at a cycle of 1 μs or more and 100 μs or less.

9. The plasma processing apparatus of claim 5, wherein the plurality of outer slots include a plurality of first outer slots and a plurality of second outer slots which are arranged alternately along the circumferential direction,
wherein the plurality of portions include:
a plurality of first portions which are either the central portions of the plurality of first outer slots in the circumferential direction or portions arranged along the central portions of the plurality of first outer slots in the circumferential direction; and
a plurality of second portions which are either the central portions of the plurality of second outer slots in the circumferential direction or portions arranged along the central portions of the plurality of second outer slots in the circumferential direction, and
wherein the plurality of short-circuiting mechanisms are configured to repeat:
creating a first state in which the plurality of first portions are released from the short-circuiting to the ground and the plurality of second portions are short-circuited to the ground;
after the first state, creating a second state in which the plurality of first portions are short-circuited to the ground and the plurality of second portions are released from the short-circuiting to the ground; and
after the second state, creating a third state in which the plurality of first portions and the plurality of second portions are short-circuited to the ground.

10. The plasma processing apparatus of claim 9, wherein the plurality of short-circuiting mechanisms are configured to sequentially switch between the first state, the second state, and the third state at a cycle of 1 μs or more and 100 μs or less.

11. The plasma processing apparatus of claim 1, wherein the resonator includes:
an inner circumferential portion extending around the central axis;
a first outer circumferential portion extending around the central axis;
a second outer circumferential portion extending around the central axis inside the first outer circumferential portion;
the waveguide having a layered structure in which the waveguide extends between the first outer circumferential portion and the inner circumferential portion, folds backward along the inner circumferential portion, and extends between the inner circumferential portion and the second outer circumferential portion;
an upper portion located in an uppermost layer of the layered structure and configured to provide the first end at the first outer circumferential portion; and
a lower portion located in a lowermost layer of the layered structure and configured to provide the second end at the second outer circumferential portion.

12. A plasma generating method in the plasma processing apparatus of claim 6, the plasma generating method comprising:
(a) supplying the electromagnetic waves to the plurality of outer slots and the plurality of inner slots via the waveguide so that the electromagnetic waves are supplied to the plasma generation space; and
(b) adjusting the short-circuiting of the plurality of portions to the ground and the release of the short-circuiting by the plurality of short-circuiting mechanisms to adjust an amount of electromagnetic waves emitted from at least one of the plurality of inner slots or the plurality of outer slots.

13. The plasma generating method of claim 12, wherein in (b), the short-circuiting of the plurality of portions to the ground and the release of the short-circuiting are switched at a cycle of 1 μs or more and 100 μs or less.

14. A plasma generating method in the plasma processing apparatus of claim 9, the plasma generating method comprising:
(a) supplying the electromagnetic waves to the plurality of outer slots and the plurality of inner slots via the waveguide so that the electromagnetic waves are supplied to the plasma generation space;
(b) creating a first state in which the plurality of first portions are released from the short-circuiting to the ground and the plurality of second portions are short-circuited to the ground by the plurality of short-circuiting mechanisms;
(c) after (b), creating a second state in which the plurality of first portions are short-circuited to the ground and the plurality of second portions are released from the short-circuiting to the ground by the plurality of short-circuiting mechanisms;
(d) after (c), creating a third state in which the plurality of first portions and the plurality of second portions are short-circuited to the ground; and
(e) sequentially repeating (b), (c), and (d).

15. The plasma generating method of claim 14, wherein the first state, the second state, and the third state are sequentially switched at a cycle of 1 μs or more and 100 μs or less.
